(19) United States
(12) Patent Application Publication
(10) Pub. No.: US 2012/0197557 A1
(43) Pub. Date: Aug. 2, 2012

(54) String Failure Monitoring

(75) Inventors: Gerd Bettenwort, Kassel (DE); Jens Klein, Goettingen (DE); Marc Schaefer, Fuldatal (DE); Jochen Fischer, Baunatal (DE); Wolfgang Frees, Kassel (DE); Matthias Victor, Niestetal (DE)

(73) Assignee: SMA Solar Technology AG, Niestetal (DE)

(21) Appl. No.: 13/410,452

(22) Filed: Mar. 2, 2012

Related U.S. Application Data
(63) Continuation of application No. PCT/EP2010/062829, filed on Sep. 1, 2010.

(30) Foreign Application Priority Data
Sep. 2, 2009 (EP) 09169281.4

(51) Int. Cl. G01R 31/02; G06F 19/00

(52) U.S. Cl. 702/58; 324/537

(57) ABSTRACT

A method of monitoring a plurality of strings of a photovoltaic system connected to a power inverter includes measuring current values from individual strings to the power inverter; determining a reference current value from the measured current values; and standardizing the measured current values to the reference current value. The method further includes and analyzing the standardized current values of individual strings within representative time periods by comparison with comparison values established for the individual strings. Based on the analysis a failure of an individual string is ascertained.

### CROSS REFERENCE TO RELATED APPLICATIONS

This application is a continuation of International Application PCT/2010/062829, filed on Sep. 1, 2010, that claims priority to co-pending European Patent Application No. 09 169 281.4 entitled “Stringausfallueberwachung”, filed on Sep. 2, 2009.

### FIELD

The present invention generally relates to a method for monitoring a plurality of strings of a photovoltaic system for a string failure. More particularly, the present invention relates to a method of monitoring a plurality of strings of a photovoltaic system connected to a power inverter.

### BACKGROUND

A method of monitoring a plurality of strings of a photovoltaic system connected to a power inverter is known from EP 0 677 749 A2. Here, the individual strings actually comprise solar modules connected in series; however, an additional parallel connection of the solar modules is also mentioned. The amperages of the currents flowing from the individual strings over a time period from 10:00 to 14:00 hours are averaged for each string. The highest averaged current amperage is established as a reference current value. As an alternative, it is mentioned that an average value of the averaged amperages of all the strings is used as a reference current value. The averaged amperages determined for the individual strings are then standardized to the reference current value. A short-term string failure is to be recognized here in that the averaged current amperage of a string standardized to the reference current value is only, for example, 0.8, i.e. 80%, or less. A long-term failure of a string is to be recognized in that, for each string, an initial averaged current amperage standardized to the reference current value is stored, and the averaged current amperage newly occurring every day standardized to the reference current value of the respective day are compared with this comparison value. If a drop in the order of magnitude of 3-5% is observed, this is interpreted as an indication of a starting failure of the respective string.

The known method of monitoring a plurality of strings proves not to be adequately sensitive to recognize the failure of only one of a plurality of substrings of a string. In current photovoltaic systems, for example, 40 substrings are combined to form a string, which is connected by one pair of bus lines to a power inverter. The failure of a substring of a string of this type means a reduction in the current supplied by only 2.5%. Thus, with the known method, not even a total failure of one substring of a string of this type would be recognized.

Thus, there still is a need for a method of monitoring a plurality of strings of a photovoltaic system connected to a power inverter, which has an adequately high sensitivity to respond even in the event of the failure of only one of very many substrings connected in parallel of a string, but nevertheless does not tend to falsely assume a (sub)string failure.

### SUMMARY

A method of monitoring a plurality of strings of a photovoltaic system connected to a power inverter comprises measuring current values of currents which flow from each of the plurality of strings to the power inverter over a plurality of predetermined time periods each day, and determining a reference current value from the measured current values for each of the plurality of predetermined time periods. The method further comprises standardizing the measured current values of each of the plurality of strings for each of the predetermined time periods using the determined reference current value, and establishing comparison values for each of the plurality of strings using the standardized measured current values over a plurality of days. Lastly, the method comprises analyzing a course of the standardized measured current values measured over a plurality of representative time periods each extending over a plurality of predetermined time periods using the established comparison values to ascertain whether an individual string of the plurality of strings exhibits a failure.

In one embodiment of the invention, analyzing further comprises updating the established comparison values for each of the plurality of strings on a periodic basis using the standardized measured current values of each of the plurality of strings measured over the representative time periods such that a alteration in one direction of the standardized measured current values of the plurality of strings over a plurality of representative time periods results in an alteration in the same direction of the updated established comparison values. The analyzing still further comprises determining differences between the standardized measured current values measured over the representative time periods and the updated comparison values for each of the plurality of strings, and calculating a sum of the differences determined for each string of the plurality of strings. Lastly, the analyzing comprises comparing the sum calculated for each string of the plurality of strings with a limit value for the respective string, and indicating a failure of the respective string if the sum calculated for the respective string exceeds a limit value for the respective string.

The present invention relates to a method of monitoring a plurality of strings of a photovoltaic system connected to a power inverter, the method comprises the steps of: measuring current values of currents which flow from the individual strings to the power inverter; determining a reference current value from each plurality of contemporaneously measured current values, and standardizing the current values of each plurality of contemporaneously measured current values to the reference current value determined for the respective plurality of contemporaneously measured current values. The method further comprises establishing comparison values for the individual strings; and analyzing long-term courses of the standardized current values of the currents which have flowed from the individual strings within representative time periods by comparison with the comparison values established for the individual strings. In this method the step of analyzing comprises: updating the comparison values established for the individual strings using the standardized currents which have flowed from the individual strings within the representative time periods such that a long-term alteration of the standardized current values of the currents which have flowed from one of the individual strings in one direction results in an alteration of the comparison value established for that same one of the individual strings in the same direction. In addition, the analyzing comprises determining differences between the standardized current values of the currents which have flowed from the individual strings within the representative time periods and the updated comparison values; continuously calculating a sum of the differences determined for each individual string; continuously comparing the sum calculated for each individual string with a limit value for the respective individual string; and indicating a failure of an individual string, if the sum calculated for each individual string exceeds the limit value for the respective individual string.

In a more detailed aspect of the present invention, a method of monitoring a plurality of strings of a photovoltaic system connected to a power inverter, the method comprises: measuring current values of currents which flow from the individual strings to the power inverter; determining a reference current value from each plurality of contemporaneously measured current values; and standardizing the current values of each plurality of contemporaneously measured current values to the reference current value determined for the respective plurality of contemporaneously measured current values. The method further comprises establishing comparison values for the individual strings; and analyzing long-term courses of the standardized current values of the currents which have flowed from the individual strings within representative time periods by comparison with the comparison values established for the individual strings. In this method the step of analyzing comprises: updating the comparison values established for the individual strings using the standardized currents which have flowed from the individual strings within the representative time periods, wherein the updated comparison value for each individual string is a weighted average value of the standardized current values of the currents which have flowed from the individual string within prior representative time periods. In addition, the analyzing further comprises determining differences between the standardized current values of the currents which have flowed from the individual strings within the representative time periods and the updated comparison values; and standardizing each difference determined for one of the individual strings to the updated comparison value for that same one of the individual strings. Lastly, the analyzing further comprises continuously calculating a sum of the standardized differences determined for each individual string, wherein the sum continuously calculated for each of the individual strings is a weighted sum of the differences determined for the individual strings, and wherein a deduction is made for each summand from the sum continuously calculated for each of the individual strings, to take into account statistical fluctuations in the measured current values; continuously comparing the sum calculated for each individual string with a limit value for the respective individual string; and indicating a failure of an individual string, if the sum calculated for each individual string exceeds the limit value for the respective individual string.

Other features and advantages of the present invention will become apparent to one with skill in the art upon examination of the following drawings and the detailed description. It is intended that all such additional features and advantages be included herein within the scope of the present invention, as defined by the claims.

### BRIEF DESCRIPTION OF THE DRAWINGS

The invention can be better understood with reference to the following drawings. The components in the drawings are not necessarily to scale, emphasis instead being placed upon clearly illustrating the principles of the present invention. In the drawings, like reference numerals designate corresponding parts throughout the several views.

FIG. 1 is a diagram showing the connection of a plurality of strings composed of a plurality of respective substrings of a photovoltaic system to a power inverter feeding electric energy from the photovoltaic system into an alternating current network.

FIG. 2 is a flow chart of the method according to one embodiment.

FIG. 3 is a graph illustrating the course of current amperages of currents which have flowed from six strings during one day.

FIG. 4 is a graph illustrating the course of the current amperages according to FIG. 3 after standardisation.

FIG. 5 is a graph illustrating the course of the current amperages of the currents which have flowed during one day when a substring has failed.

FIG. 6 is a graph illustrating the course of the current amperages according to FIG. 5 after standardisation.

### DETAILED DESCRIPTION

The method comprises the steps of measuring current values of currents that flow from the individual strings to the power inverter, determining a reference current value from each plurality of contemporaneously measured current values, and standardizing the current values of each plurality of contemporaneously measured current values to the reference current value determined for the respective plurality of contemporaneously measured current values. The method further comprises establishing comparison values for the individual strings, and analyzing long-term courses of the standardized current values of the currents that have flowed from the individual strings within representative time periods by comparison with the comparison values established for the individual strings.

The term string indicates a series connection, in which a plurality of solar modules of a photovoltaic system is arranged. Accordingly, in the method disclosed here, each string may be a series connection of this type of a plurality of solar modules. However, generally, each row of solar modules of a photovoltaic system is not separately connected to a power inverter in such a way that the current flowing from each row of solar modules can be detected separately, but a plurality of rows of solar modules of this type are combined together and connected to the power inverter by a pair of bus lines. Only the current flowing via these bus lines and generated by a plurality of rows of solar modules connected in parallel is detected separately. Accordingly, the term “string” in this description designates, in particular, a parallel connection of a plurality of series connections of solar modules, which are connected as a unit by a pair of bus lines to a power inverter.

If in a string, the current flowing to the power inverter is monitored separately, a plurality of rows of solar modules are connected in parallel, wherein each row may be called a substring of the string, the failure of a substring only becomes noticeable as a partial drop of the current generated by the string, the size of which depends on the number of substrings connected in parallel. The present invention particularly deals with methods, which are adequately sensitive to monitor strings for a failure of a substring, which strings comprise a plurality of substrings, like for example 40 substrings or more.

In the methods disclosed here, the current values of the currents that flow from the individual strings to the power inverter are either current amperages or current powers, and they are measured at measuring instants or during measuring periods (as average values or integral values). As the current powers of the currents that have flowed are generally determined as products of the measured values of the current amperages and of the associated voltages, a detailed description of the current amperage case always is also a detailed description of the current power case. Thus, each of the following explanations of the current amperage case of the method also applies to the current power case of the method, taking into account the conversion of the current amperages observed there by multiplication with the associated voltages into the corresponding current powers.

According to the method disclosed here, current values of the currents flowing from the individual strings to the power inverter are measured to monitor a plurality of strings of a photovoltaic system connected to a power inverter. In one embodiment, a current value for each string is determined as an average value of the current amperage over a measuring period of a few seconds to a few minutes, which is the same for all the strings. Then, the next set of current values is determined in the same manner for a following measuring period of the same length. In this manner, current values are measured and recorded over the entire day or another representative time period. Thereafter or already in parallel thereto, a reference current value is determined for each measuring period from the current values of the currents which have flowed from the individual strings. As known from the prior art, this may be a maximum value or an average value of the measured current values. However, in one embodiment the median of the measured current values is employed as a reference current value. This reference current value is used to standardize the measured current values of the currents which have flowed from the individual strings, for example, in the same measuring period, in order to rule out influences which relate to all the strings equally, such as, for example, different insolations, prior to further assessing the current values. In the case of shorter measuring periods, it is also possible to use a reference current determined for an earlier measuring period for the standardization instead of the reference current determined for the same measuring period.

To the end of analyzing the long-term courses of the standardized current values of the currents that have flowed from the individual strings within representative time periods, in order to recognize a failure of a string, even if only one of many substrings of the string is affected by this, comparison values are established in the method disclosed here. The comparison values are established based on at least one of the representative time periods. However, in one embodiment the method takes into account a plurality of representative time periods in order to compensate for individual events and statistical fluctuations. For this purpose, the standardized current values of the currents that have flowed in the plurality of representative time periods are observed and a comparison value is established from them. This comparison value is a relative current, such as it typically flows from the observed string in comparison to the currents of other strings. Firstly, for each representative time period, for example a day, a selected part of a day or a plurality of days, a representative current value is established from the standardized current values determined previously for this representative time period. This may be an average value of the individual values of the standardized current values, which were determined for the representative time period. The representative current value can also be established by fitting a function to the standardized current values of the currents that have flowed over the representative time period, and by determination, for example, of the average value or maximum value of this function during the representative time period. However, in one embodiment the median of these standardized current values is used as the representative current value. Any influence on the standardized current values of the individual strings, which includes only a partial time period of the representative time period, which is not greater than half the representative time period, remains virtually without any effect in the method disclosed here when the median of the standardized current values is used as the representative current value of the representative time period. Conversely, a drop in the current value as a result of a failure of a substring, as long as this drop has an effect over more than half of the representative time period, becomes particularly clearly noticeable in the median, i.e. clearer than with an average value over the representative time period. When observing these representative current values for a plurality of representative time periods to establish the comparison values for each individual string, an average value formation over the representative currents or the determination of the median can also take place.

In the method disclosed here, the comparison values established for the individual strings are not constant, but they are updated taking into account the standardized current values of the currents which have flowed from the individual strings within the further representative time periods. Long-term changes of the relative current values of the currents from the individual strings thus lead to a change in the comparison values established for them. Thus, slow but nevertheless premature degradations of individual strings may not be recognized with the method disclosed here. This can, however, be compensated for by an additional comparison of the present standardized current values with the originally established comparison values. Conversely, the updating of the comparison values for the individual strings ensures increased sensitivity of the method disclosed here relative to short-term failures of substrings of a string, even if several tens of substrings, such as, for example, 40 or more substrings, are connected in parallel in this string.

In addition, in the method disclosed here, in one embodiment it is not checked only once whether a representative standard current deviates by a specific amount from the associated updated comparison value and already decided then whether a failure occurred, but, rather, the differences between the updated comparison values and the corresponding standardized current values of the currents that have flowed from the individual strings within the respective last representative time period are formed and summed up. This sum is firstly compared with a limit value, which may be established individually for each string, and when this limit value is exceeded by the sum of the differences, a failure of the respective string is recognized. It is to be noted here that the summands of this sum may not only be positive, as if the value for the last representative time period remains behind the current updated comparison value, but also negative, as if the last representative value exceeds the current updated comparison value. The sum of the differences therefore does not only increase, but may also drop (again). Moreover, in one embodiment this sum is not a direct sum total of the differences, but these differences are weighted before being added to the respective previous sum, and additional regular deductions are made from the sum in order to compensate for statistical effects, as will be described below in more detail.

In order to allow for a direct comparison of the sums of the differences of the individual strings with one another and with a limit value applying to all the strings, the differences can be standardized before the calculation of their sum, in each case to the associated updated comparison value.

As it was already indicated, in the method disclosed here, a deduction is made in one embodiment from the continuously formed sum for each string for each summand added in order to take into account statistical fluctuations in the measured currents. Accordingly, this deduction may depend on the standard deviation of the measured values of the standardized current values. The deduction may, however, also be carried out in the form of a fixed predetermined value.

It was also already indicated that the sum continuously calculated for each string is not a direct sum total of the differences formed, but weighting factors are taken into account. Specifically, a weighting factor of the respective current value difference may increase with the respectively previously determined sum, if the current value difference is positive, in other words is also indicating a current value of the current that has flowed from the respective string below the updated comparison value. As a result, the sum rapidly increases with positive differences of this type, if it had already reached a certain value beforehand.

Furthermore, weighting factors for positive differences of this type may increase with the frequency of large positive differences. If—in other words—in the recent past, large positive differences have already repeatedly occurred, which indicates a string failure, the positive differences occurring beyond this are more strongly weighted than if such events had not occurred in the recent past.

However, if there are indications that an individual string is neither threatened by a failure nor has even been affected by a failure, the weighting factor of positive differences for this string, which has increased with the frequency of large positive differences, may be reduced again for the future. The occurrence of a negative difference can be used as the triggering criterion for the reduction in the weighting factor according to one embodiment.

The comparison value for each string is, in one embodiment, calculated with weighted consideration of standardized current values of currents that have flowed from the string within the earlier representative time periods. The updated comparison value for each string is, in one embodiment, a weighted average value of the last comparison value and a median of the representative current values for a specific number of last representative time periods, the weighting factor of this median being all the smaller, the clearer the indications are that the respective string is affected by a failure. In other words, the comparison value should only be altered by the updating, if no failure indications of this type are present. Thus, the weighting factor for the current representative current value can be reduced with an increasing associated difference and/or increasing associated sum and/or increasing number of large positive differences.

In the method disclosed here according to one embodiment, in order to detect failures of strings, whole days or equivalent equal parts of whole days are observed as the representative time period, such as, for example, a time period of equal length around noon.

In addition, the day's course of the standardized current values of the individual strings may be analyzed. As a result, for example, shadings of individual strings related to the time of day can be discovered, or poor ventilation of individual strings can be recognized at the maximum thermal loading at noon, in order to thereby counteract connected power losses. A shading typically becomes noticeable by a temporary drop in the standardized current values of the currents that have flowed, which frequently occurs in the evening and in the morning. Poor ventilation of a string becomes noticeable, in particular, at mid-day and at maximum insolation. Shadings related to the time of day or poor ventilation of individual strings, apart from the analysis of standardized current values, can also be discovered by evaluation of correspondingly standardized voltages across the individual strings.

The method disclosed here is based on measuring current values of the currents, that flow from whole strings during operation of a photovoltaic system. Nevertheless, the method disclosed here is sensitive enough to recognize the failure even of only one substring of a large number of substrings of a string with the aid of these measured current values. The necessity of attaching a sensor system to monitor the individual substrings at the site of the strings is therefore dispensed with. Instead, the method disclosed here can be carried out at the site of the power inverter, which feeds the electric power from the photovoltaic system into an alternating current network. In particular, it can be implemented in existing devices for measuring the current values of the currents of individual strings and with adequate storage capacities for the measured current values to be evaluated in the form of software to control the power inverter.

It is to be noted that one could use reciprocal values of the standardized current values and comparison values or of the differences between them for further evaluation, without deviating from the scope of the present invention as, due to the standardization forming part of the method disclosed here, this use of reciprocal values instead of the original values would make little to no difference to the performance of the method disclosed here.

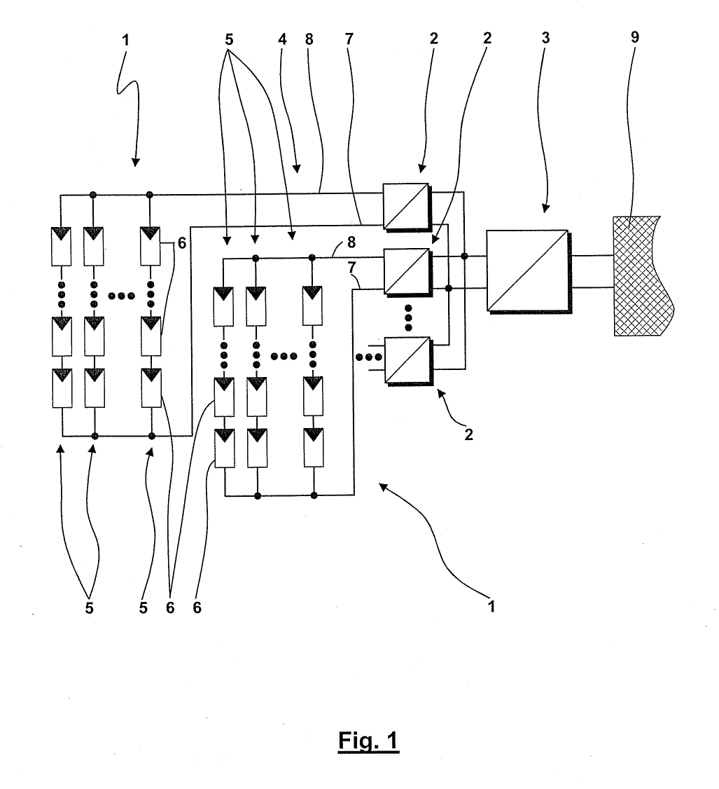

Referring now in greater detail to the drawings, FIG. 1 illustrates the connection of a plurality of strings 1, by means of a respective connection device 2 each, to a power inverter 3 for feeding electric energy from a photovoltaic system 4 formed by the strings 1 into an alternating current network 9. Each string 1 consists of a large number of substrings 5 connected in parallel to one another. Each substring 5 in turn comprises a large number of solar modules 6 connected in series. Neither the number of substrings 5 nor of the solar modules 6 is completely reproduced here for the strings 1. The same applies to the number of strings 1. Each connection device 2 at least comprises a measuring device for measuring the current amperage of current flowing from the individual string 1 to the power inverter 3. During operation of the photovoltaic system 4, i.e. during feeding electric energy into the alternating current network 9 by means of the power inverter 3, the output voltage of all the strings 1 between their respective bus lines 7 and 8, to which all their substrings are connected, is the same. The involvement of the individual strings 1 in the electric energy, which is fed into the alternating current network 9, is therefore completely reflected in the current amperages of the currents flowing from the individual strings 1, which are detected by the connection device 2.

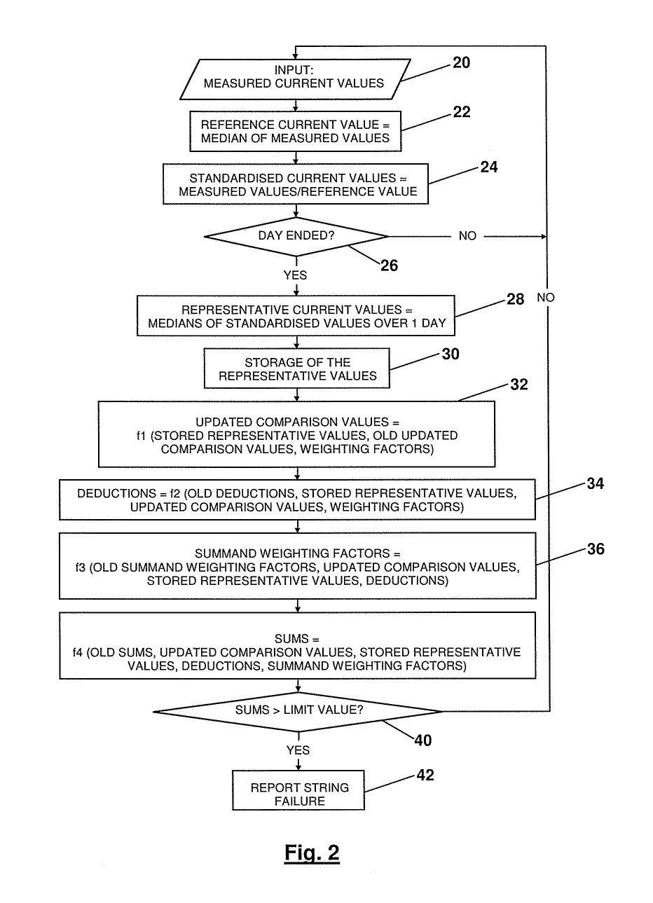

FIG. 2 is a flow chart of a method of monitoring the strings 1 according to FIG. 1, which recognizes the failure of even only one of, for example, 40, substrings 5 connected in parallel in each string 1. The number of substrings 5 may be the same in all strings 1; it may, however also vary between the strings 1. This method starts from measured current values of the connection device 2 according to FIG. 1 at 20, which are, for example, average values of the current amperages measured within a measuring period of 10 seconds. For each of these measuring periods of 10 seconds, a reference current is determined from these measured current values at 22. According to the embodiment of FIG. 2, the median of the measured current values of all the strings is used for this. Using this reference current value, standardized current values are calculated from the measured current values in that the measured current values are divided by the reference current value at 24. This is carried out for all the measuring periods of 10 seconds during the entire day.

At the end of each day determined at 26, for each string, a representative current value is determined for the day at 28. This is the median of the standardized current values here in one embodiment. These representative current values are stored for all the strings. A comparison value is established for each string from the representative current values stored for several days for the respective string, also in the form of the median of the representative current values over these days in one embodiment. Only after comparison values for all the strings have been established in this manner, the further method steps according to FIG. 2 proceed at the end of each day. The comparison values for the strings are in each case updated as a function f1 of the old updated comparison value and of a median of the representative current values stored for a number of the last day and of weighting factors at 32. The weighting factor for the median are all the lower, the larger the indications already present are for the fact that this string is affected by a failure. Using the presently updated or still the old updated comparison values, a sum of the differences between these updated comparison values and the stored representative current values of the last day is then calculated for each string at 34. In this step, the current difference is not added as a direct summand, but with a summand weighting factor. In addition, a constant deduction or a deduction depending on the standard deviations of the standardized currents is made from each summand. It is obvious that in the case of negative differences, i.e. representative current values of a string above its updated comparison value, the resulting summands are also negative.

The summand weighting factors are, in each case, a function f3 of the old summand weighting factors, the updated comparison values, the stored representative current values of the last day and of deductions at 36. These deductions are also updated values, which are a function f2 of the old deductions and are influenced by the stored representative values, the updated comparison values and weighting factors.

The comparison of the current sum for the respective string with a limit value is decisive in establishing whether a string has failed. Exceeding the limit value at 40 indicates a string failure which will be reported at 42. Owing to the observation of the sum calculated according to the method disclosed here for each string, instead of only a difference between the respective current value and a fixed comparison value, the method disclosed here is robust in the face of statistical fluctuations and other non-specific influences on the evaluated measured values. The sensitivity of the method disclosed here can therefore be adjusted to be very high without the false display of string failures. Specifically, the gradual failure of a substring 5 according to FIG. 1 over a time period of several days can be selectively recognized, even if this failure indicates a partial drop in the current of the entire string 1 over this period of only, for example, 2.5% or less.

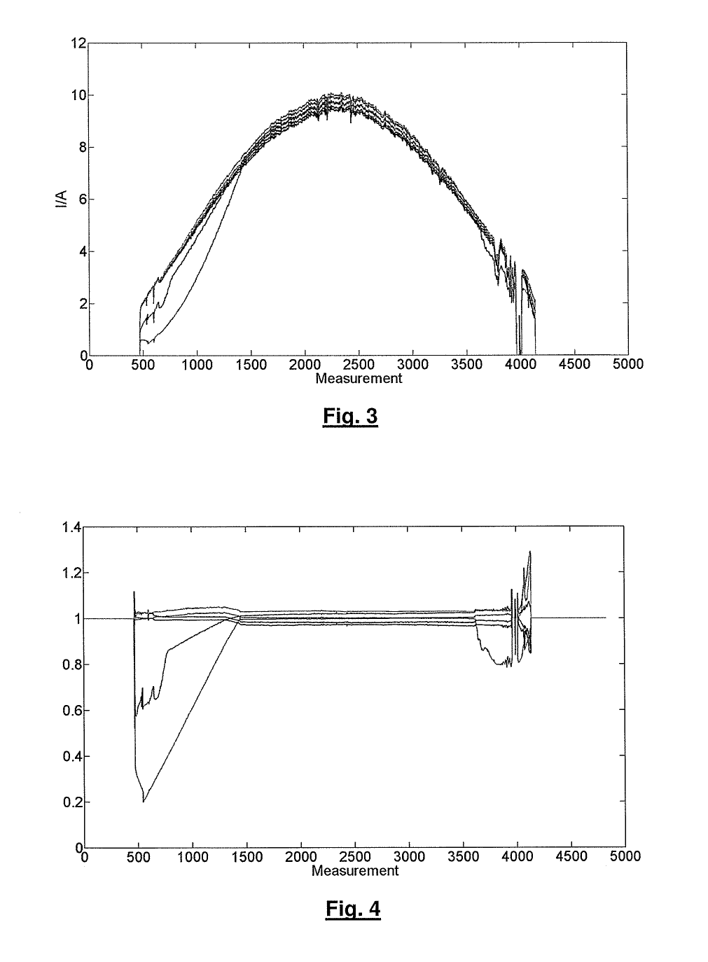

FIG. 3 shows the measured current amperages for six strings over one day, in which about 4,000 measurements, i.e. about 4,000 average values, are determined over a time period of 10 seconds, in each case. It can be seen from FIG. 3 that the current amperages of two strings are below an average level in the morning because they are partially shaded at this time. A similar effect occurs in one string in the evening.

FIG. 4 represents the current amperages standardized to the median of the measured current amperages during each measuring period of 10 seconds for the same day as in FIG. 3. Apart from the morning, where the shadings of the two strings are even clearer than in FIG. 3, and in the evening, where the shading of a string taking place at this time can easily be seen, the relative currents of the individual strings have substantially constant values. If the median of the standardized current amperages according to FIG. 4 is determined for each string, a representative current value which is independent of all the partial shadings and other temporary effects during a day is produced.

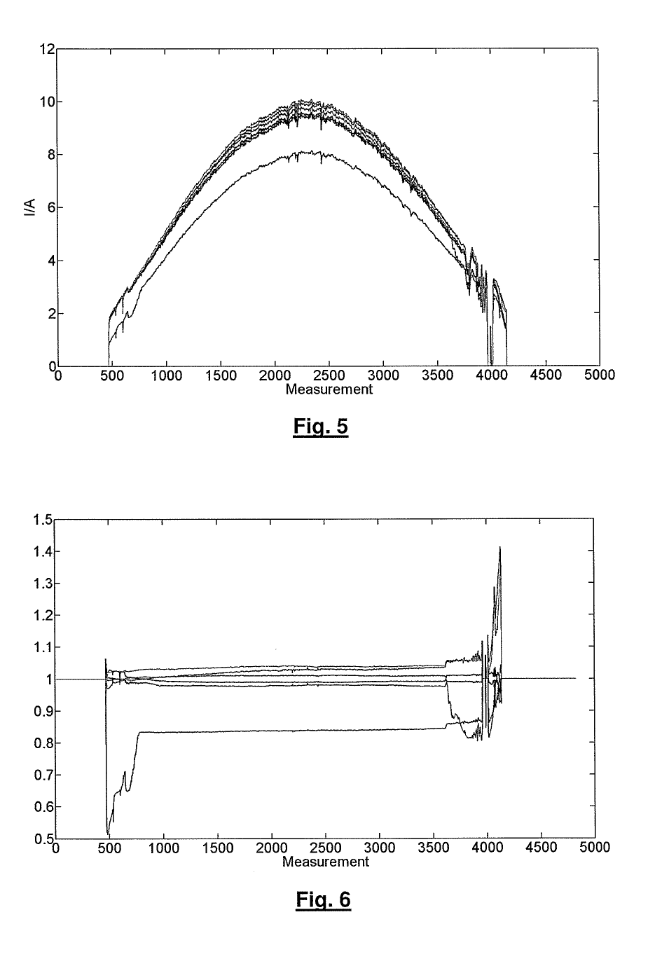

FIG. 5, in a diagram corresponding to FIG. 3, shows the measured current amperages of six strings, of which one only supplies a reduced current because of the failure of a substring.

The depiction of the corresponding standardized current amperages according to FIG. 6 shows, a clearly lowered value for this substring, which very rapidly leads to a high sum and therefore an exceeding of the limit value in the method sketched in FIG. 2.

Many variations and modifications may be made to the preferred embodiments of the invention without departing substantially from the spirit and principles of the invention. All such modifications and variations are intended to be included herein within the scope of the present invention, as defined by the following claims.

1. A method of monitoring a plurality of strings of a photovoltaic system connected to a power inverter, the method comprising:
measuring current values of currents which flow from each of the plurality of strings to the power inverter over a plurality of predetermined time periods each day;
determining a reference current value from the measured current values for each of the plurality of predetermined time periods;
standardizing the measured current values of each of the plurality of strings for each of the predetermined time periods using the determined reference current value;
establishing comparison values for each of the plurality of strings using the standardized measured current values over a plurality of days; and
analyzing a course of the standardized measured current values measured over a plurality of representative time periods each extending over a plurality of predetermined time periods using the established comparison values to ascertain whether an individual string of the plurality of strings exhibits a failure.

2. The method of claim 1, wherein the step of analyzing further comprises:
updating the established comparison values for each of the plurality of strings on a periodic basis using the standardized measured current values of each of the plurality of strings measured over the representative time periods such that a alteration in one direction of the standardized measured current values of the plurality of strings over a plurality of representative time periods results in an alteration in the same direction of the updated established comparison values;
determining differences between the standardized measured current values measured over the representative time periods and the updated comparison values for each of the plurality of strings;
calculating a sum of the differences determined for each string of the plurality of strings;
comparing the sum calculated for each string of the plurality of strings with a limit value for the respective string; and
indicating a failure of the respective string if the sum calculated for the respective string exceeds a limit value for the respective string.

3. The method of claim 1, wherein the measured current values are selected from one of current amperages and current powers of the currents that flow from each string of the plurality of strings to the power inverter.

4. The method of claim 1, wherein the current values of the measured currents are selected from currents flowing at a measuring instant within each of the predetermined time period and currents flowing during the predetermined time periods.

5. The method of claim 2, wherein each difference determined for one string of the plurality of strings is standardized to the updated comparison value for that same one string of the plurality of strings prior to calculating the sum for that same one string.

6. The method of claim 2, further comprising deducting for each summand a predetermined value from the calculated sum for each string of the plurality of strings, in order to take into account statistical fluctuations in the measured current values.

7. The method of claim 2, wherein the calculated sum for each string of the plurality of strings is a weighted sum of the differences determined for the respective strings.

8. The method of claim 2, wherein weighting factors of positive differences increase with a previously calculated sum for each respective string.

9. The method of claim 7, wherein weighting factors of positive differences increase with a frequency of occurrence of large positive differences exceeding a difference limit value.

10. The method of claim 9, wherein the weighting factors of positive differences that have increased with the frequency of occurrence of large positive differences are reduced on the occurrence of a negative difference.

11. The method of claim 2, wherein the updated comparison value for each string of the plurality of strings is a weighted average value of the standardized current values for the respective string within prior representative time periods.

12. The method of claim 11, wherein weighting factors for newly added standardized current values are reduced with an increase of at least one of the following values: the difference determined for the respective standardized current value, the sum calculated for the respective standardized current value, and a number of large positive differences determined for the respective individual string within an observation period extending over a plurality of representative time periods.

13. The method of claim 11, wherein the representative time periods are selected from whole days, identical parts of whole days and pluralities of a fixed number of days.

14. The method of claim 1, further comprising:
analyzing the standardized current values of each string of the plurality of strings over a course of a single day.

15. The method of claim 1, further comprising:
analyzing voltages associated with each string of the plurality of strings that are standardized in a way corresponding to the standardization of the measured currents values of the respective strings.

16. The method of claim 1, wherein the determined reference current value for each string and each representative time period is selected from:
a single value of the measured current values of the respective string measured over the respective representative time period, a single value of the measured current values measured over a representative time period directly preceding the respective representative time period,
a median of the measured current values of the respective string measured over the respective representative time period,
a median of the measured current values of the respective string measured over a representative time period directly preceding the respective representative time period,
an average value of the measured current values of the respective string measured over the respective representative time period, and an average value of the measured current values of the respective string measured over a representative time period directly preceding the respective representative time period.

17. The method of claim 1, wherein the comparison value for each string of the plurality of strings is established as one of the following:
a median of a plurality of standardized current values within a plurality of representative time periods, and
an average of a plurality of standardized current values within a plurality of representative time periods.

18. The method of claim 1, wherein all steps of the method are carried out at a site of the power inverter.
